(19) United States
(12) Patent Application Publication
(10) Pub. No.: US 2023/0317476 A1
(43) Pub. Date: Oct. 5, 2023

(54) DIRECT INJECTION FILLING DEVICE, SYSTEM, AND METHOD FOR LIQUID METAL INTERCONNECTS

(71) Applicant: Intel Corporation, Santa Clara, CA (US)

(72) Inventors: Sangeon Lee, Chandler, AZ (US); Tingting Gao, Chandler, AZ (US); Xiao Lu, Chandler, AZ (US); Jiaqi Wu, Chandler, AZ (US); Matthew T. Magnavita, Chandler, AZ (US); Andrew W. Carlson, Phoenix, AZ (US)

(73) Assignee: Intel Corporation, Santa Clara, CA (US)

(21) Appl. No.: 17/712,090

(22) Filed: Apr. 2, 2022

(51) Int. Cl. H01L 21/67; H01L 23/498; H01L 21/48

(52) U.S. Cl. CPC H01L 21/6715; H01L 23/49811; H01L 21/4853; H01L 21/4867

(57) ABSTRACT

In one embodiment, a direct injection device includes a head, a plunger, a reservoir, and multiple needles. The head controls extrusion of liquid stored in the reservoir of the direct injection device. For example, the head causes the plunger to compress the liquid in the reservoir, which causes the liquid to be extruded through the needles.

### BACKGROUND

The high conductivity and fluidity of liquid metal makes it a promising candidate as an electrical conductor directly dispensable at room temperature. Unlike conventional metals in the solid state, the intrinsic nature of liquid metal is naturally soft, which enables it to be easily dispensed, patterned, deformed, and even stretched to form desired structures. These properties make liquid metal very appealing for the design of interconnect technologies. Current manufacturing processes for liquid metal interconnects have various downsides, however, including low quality filling, low yield, and inability to scale, which renders them unsuitable for high-volume manufacturing (HVM).

### BRIEF DESCRIPTION OF THE DRAWINGS

FIGS. 1A-C illustrate an example of using direct injection to form a liquid metal interconnect in a substrate.

FIG. 2 illustrates a liquid metal direct injection system in accordance with certain embodiments.

FIGS. 3A-B illustrate examples of successful and unsuccessful direct injection filling sequences.

FIGS. 4A-B illustrate an example of using direct injection to fill a 6×6 substrate with liquid metal.

FIGS. 5A-C illustrate example renderings of the liquid metal fill quality in the substrate from FIGS. 4A-B after performing direct injection.

FIG. 6 illustrates an example embodiment of a direct injection filling tool.

FIG. 7 illustrates an example embodiment of a multi-needle direct injection tool.

FIGS. 8A-B illustrate an example embodiment of a multi-head direct injection system.

FIG. 9 illustrates an example embodiment of a multi-head single-reservoir direct injection system.

FIGS. 10A-G illustrate various stages of a manufacturing process for a socket-based integrated circuit package with a liquid metal interposer in accordance with certain embodiments.

FIG. 11 illustrates a process flow for manufacturing a socket-based liquid metal integrated circuit package.

FIG. 12 illustrates an example embodiment of a liquid metal socket system.

FIG. 13 illustrates a flowchart for forming a liquid metal interconnect using a direct injection system in accordance with certain embodiments.

FIG. 14 is a top view of a wafer and dies that may be included in a microelectronic assembly, in accordance with any of the embodiments disclosed herein.

FIG. 15 is a cross-sectional side view of an integrated circuit device that may be included in a microelectronic assembly, in accordance with any of the embodiments disclosed herein.

FIG. 16 is a cross-sectional side view of an integrated circuit device assembly that may include a microelectronic assembly, in accordance with any of the embodiments disclosed herein.

FIG. 17 is a block diagram of an example electrical device that may include a microelectronic assembly, in accordance with any of the embodiments disclosed herein.

### DETAILED DESCRIPTION

The high conductivity and fluidity of liquid metal, such as gallium (Ga)-based liquid metal alloys—makes it a promising candidate as an electrical conductor directly dispensable at room temperature. Unlike conventional metals in the solid state, the intrinsic nature of liquid metal is naturally soft, which enables it to be easily dispensed, patterned, deformed, and even stretched to form desired structures.

These properties make liquid metal very appealing for the design of interconnect technologies. For example, liquid metal arrays can be used to implement socket technologies with high-conductivity and low-resistance interconnects, which eliminates loading complexity and enables pin count scaling without the need for the higher loads required by land grid array (LGA) technology.

Current manufacturing processes for liquid metal interconnects have various downsides, however, including low quality filling, low yield, and inability to scale, which renders them unsuitable for high-volume manufacturing (HVM). For example, squeegee printing can be used to form a liquid metal interconnect by pressing liquid metal directly on the surface of the substrate using a squeegee to fill its holes with liquid metal. However, squeegee printing has various disadvantages. For example, because squeegee printing completely covers a substrate surface with liquid metal and then removes material to form the desired structures, it is a material-consuming process that generates substantial waste. In addition, squeegee printing typically suffers from partial or insufficient filling and non-filling of holes due to complications from uneven surface energy, inconsistent surface morphology, and air trapping in holes. Further, due to the very high surface tension of liquid metal (which is nearly 10 times higher than water), squeegee printing requires high pressure and multiple back-and-forth strokes to fill the holes completely, which significantly reduces manufacturing efficiency and yield. These repetitive back-and-forth strokes can also further oxidize liquid metal during printing, which increases the electrical resistance of the resulting liquid metal interconnect. Finally, the heavy material wastage associated with the cleaning process, along with the disposition of liquid-metal-contaminated cleaning cloth/paper, present unique challenges for managing the process in a clean room environment, particularly since gallium-based liquid metal is corrosive to most metals.

Accordingly, this disclosure presents embodiments of direct injection filling devices, systems, and methods for forming liquid metal interconnects. In particular, the described embodiments include a direct injection system that employs a scalable liquid metal filling process to enable high-volume manufacturing (HVM) of liquid metal interconnects.

In some embodiments, for example, the direct injection system uses a direct injection filling method to dispense liquid metal into an array of holes in a substrate to form a liquid metal interconnect. This system has the unique capability to deliver liquid metal material to specific locations (e.g., holes) with accurate volume control, which enables liquid metal to be used for both second level interconnect (SLI) applications and first level interconnect (FLI) applications.

This system may also incorporate a multi-needle injection head design to fill an entire unit (e.g., a holed substrate for a liquid metal interconnect) simultaneously to achieve the level of efficiency required for high-volume manufacturing.

Moreover, the manufacturing process employs a unit-level injection process flow that performs liquid metal filling and unit attachment in a single integrated link of the process (e.g., to form the interconnect and attach it to an integrated circuit package), which simplifies the manufacturing steps and maximizes process yield.

The described embodiments provide a comprehensive solution for high-volume manufacturing of liquid metal interconnects with key process and equipment building blocks. For example, unlike subtractive methods that start with complete surface coverage and then remove material to form desired structures (e.g., squeegee printing), the direct injection system uses less material and generates less waste by placing material only where needed. The direct injection system also has very fine and precise volume control. The direct injection process is cost effective, as a single injection step can be used to fill all the holes in a substrate with minimal wastage, which reduces manufacturing costs and provides cost savings on raw liquid metal materials.

The multi-needle injection head design enables efficient unit-level filling. Needles can be designed with different lengths to deliver liquid metal material to steps, valleys, and other hard to reach locations. Needles can also be designed with various diameters to scale with different applications.

Further, the unit-level injection process flow has less steps compared to a panel-level process flow. In particular, the unit-level injection process flow has injection, metrology, and final attach steps integrated in a single link, which provides better process control and final product yield.

Finally, the described embodiments can also be used for direct injection of other types of materials, and/or for other purposes outside the context of semiconductor processing and packaging.

Use of the devices, techniques, and structures described herein may be detectable using tools such as optical microscopy; high resolution physical or chemical analysis; chemical characterization, such as x-ray crystallography or diffraction (XRD), energy-dispersive x-ray spectroscopy (EDX), or Fourier Transform Infrared Spectroscopy (FTIR); scanning/transmission electron microscopy (SEM/TEM), scanning transmission electron microscopy (STEM), nano-beam electron diffraction (NBD or NBED), and reflection electron microscopy (REM); composition mapping; secondary ion mass spectrometry (SIMS); time-of-flight SIMS (ToF-SIMS); atom probe imaging or tomography; local electrode atom probe (LEAP) techniques; and 3D tomography, to name a few suitable example analytical tools.

For example, these analytic tools can be used to identify features indicative of liquid metal filled by direct injection, such as: a liquid metal alloy present in certain (potentially targeted) areas (e.g., holes) of a substrate; consistent filling quality of liquid metal in each area (e.g., based on the meniscus shape and metallurgy); minimal or no voiding in the liquid metal material (e.g., liquid metal dispensed by injection looks like liquid rather than paste); and/or a high volume or weight measurement per dispensed area of liquid metal; only targeted areas or holes filled with liquid material. In some embodiments, the liquid metal alloy may include elements such as, but not limited to, gallium (Ga), carbon (C), indium (In), tin (Sn), bromine (Br), and/or oxygen (O).

The direct injection devices, systems, and processes described herein can also be detected by inspecting/auditing a manufacturing line to identify the presence of equipment, tooling, and/or materials used for direct injection that incorporate any of the features described herein (e.g., direct injection tools with multiple needles, multiple heads with one or more needles per head, multiple heads with a shared reservoir, configurable/swappable modular needle arrays).

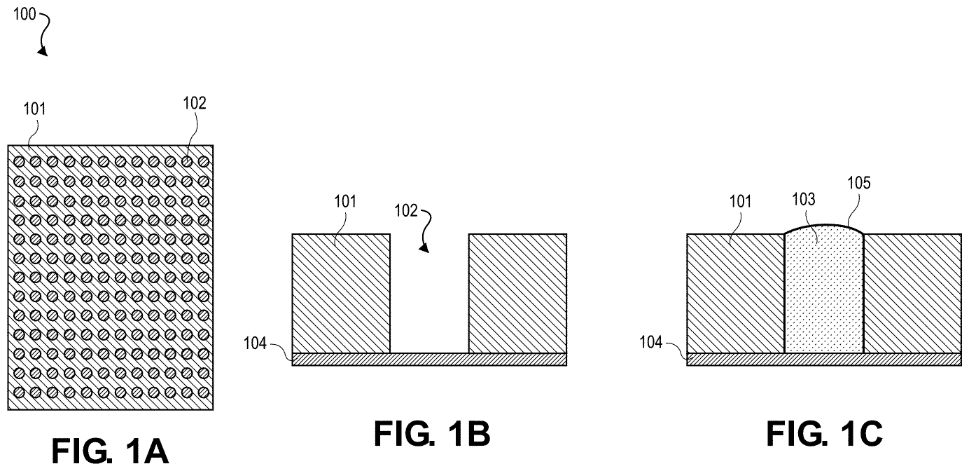

FIGS. 1A-C illustrate an example of using direct injection to form a liquid metal interconnect in a substrate 100. FIG. 1A shows a top view of a substrate 100 with an array of holes 102 for the interconnect, and FIGS. 1B and 1C show cross-section views of one of the holes 102 in the substrate 100 before and after filling it with liquid metal 103 via direct injection.

In the illustrated example, the substrate 100 includes a 12×13 array of holes 102 formed in a dielectric layer 101, which need to be filled with liquid metal to form an interconnect. The holes 102 have openings at the top of the substrate 100 and are covered by a cap 104 (e.g., a foam cap) at the bottom of the substrate 100 to prevent leakage. In actual embodiments, however, the number of holes in a substrate that need to be filled may be significantly larger, such as 3,000-10,000 holes.

Moreover, direct injection is used to fill the holes 102 with liquid metal to form an interconnect. For example, in FIGS. 1B-C, cross-section views are shown for one of the holes 102 before and after filling it with liquid metal via direct injection. As shown in FIG. 1C, the liquid metal 103 immediately forms an outer oxide shell 105 upon being directly injected into the hole 102.

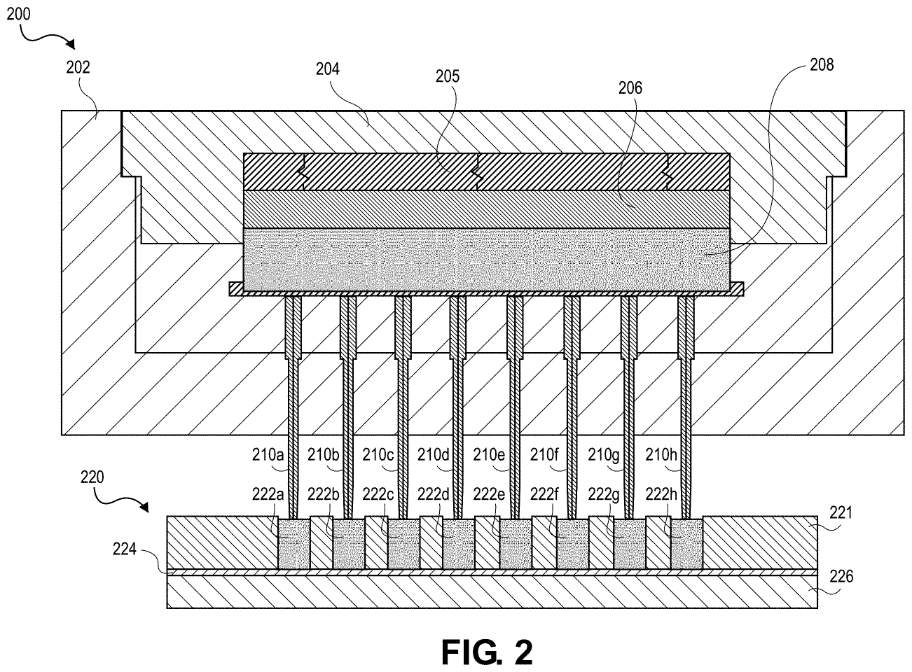

FIG. 2 illustrates a liquid metal (LM) direct injection system 200 in accordance with certain embodiments. In particular, the LM direct injection system 200 is a multi-needle dispensing system that can simultaneously fill multiple holes 222a-h of a substrate 220 with liquid metal, thus forming a liquid metal “patch” 220 that can be incorporated into an integrated circuit package (e.g., as an interconnect/interposer), as described below.

The direct injection device 200 includes a body 202, head 204, spring(s) 205, compression plate 206, liquid metal reservoir 208, and multiple needles 210a-h. The body 202 serves as a housing for the components in the device 200. The head 204 and spring 205 exert downward force on the compression plate 206, which pushes the compression plate 206 down and causes it to squeeze liquid metal in the reservoir 208 through the needles 210a-h. As a result, the liquid metal is injected into the holes 222a-h in the patch substrate 220, which forms a liquid metal patch 220. In the illustrated embodiment, the liquid metal patch 220 includes a substrate or dielectric layer 221 with multiple holes 222a-h filled with liquid metal, a cap 224 below the dielectric layer 221 to prevent leakage, and protective filler 226 below the cap 224.

In the illustrated embodiment, the system 200 includes eight needles 210a-h that are capable of simultaneously filling eight holes 222a-h on the patch substrate 220. This multi-hole dispensing design provides significantly faster dispensing speeds and much higher yield, which makes it very well-suited for high-volume manufacturing (HVM) of liquid metal interconnects. Moreover, in order to improve manufacturing efficiency, multi-needle array injection head(s) can be designed to match the hole pattern on the patch substrate 220.

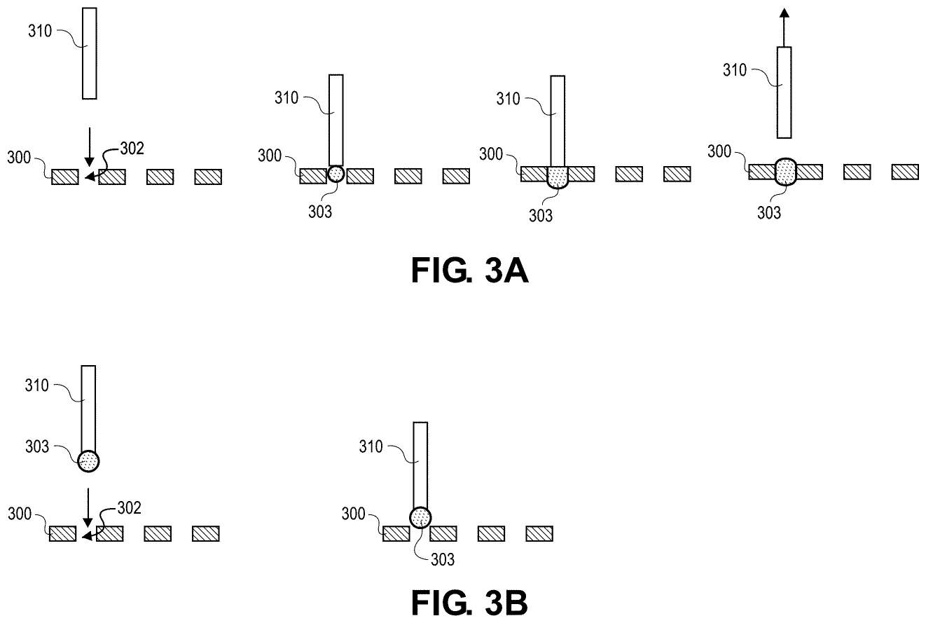

Moreover, the LM direct injection system 200 uses a novel direct injection filling approach to fill the holes 222a-h of a patch substrate 220 with liquid metal. This method is achieved by flowing liquid metal through a syringe needle 210 in close proximity to the substrate 220, which injects the liquid metal into one of the holes 222, causing the liquid metal to expand uniformly in the hole 222 instead of expanding before it reaches the hole 222 (as shown in FIGS. 3A-B). In some cases, for example, to achieve good fill quality, the needle 210 may be positioned approximately 0 to 1 millimeters (mm) from the surface of the substrate depending on the particular geometry, such as the droplet size, hole diameter, and hole depth. In other cases, however, the needle 210 may be positioned further than 1 mm from the surface of the substrate.

This direct injection process provides more accurate volume control and material cost saving. Unlike subtractive methods (e.g., squeegee printing), direct injection delivers materials only where they are needed, which minimizes material wastage since there is no need to cover the surface completely and then remove materials to form the desired structures.

FIGS. 3A-B illustrate examples of successful and unsuccessful direct injection filling sequences. The key to direct injection filling is to bring the needle 310 in close enough proximity to the substrate 300 to which the oxide shell of the metal adheres. For example, upon being injected through the needle 310, liquid metal 303 immediately forms an outer oxide shell (as shown in FIG. 1). Subsequent movement of the needle 310 creates mechanical stress that can rupture the oxide. Dispensing liquid metal 303 is a dynamic process of continually breaking and reforming the oxide layer. The increase of the oxygen content in the liquid metal 303 effectively decreases its surface tension, which helps the liquid metal 303 expand and fill the holes 302 in the patch substrate 300.

An example of a successful direction injection filling sequence is shown in FIG. 3A. In the illustrated example, the nozzle 310 is positioned in close proximity to the substrate hole 302 (e.g., by a robotic arm), pressure is applied to inject liquid metal 303 through the nozzle 310 and into the hole 302, and the liquid metal 303 then expands uniformly in all directions to fill the hole 302. The oxide layer ruptures as soon as the liquid metal touches the surface, which causes the liquid metal 303 to adhere to the inner walls of the hole 302. This method can be used to fill liquid metal into holes 302 with a controlled geometry.

An example of an unsuccessful direction injection filling sequence is shown in FIG. 3B. In the illustrated example, the nozzle 310 is not close enough to the hole 302 when the liquid metal 303 is dispensed. As a result, the liquid metal 303 expands before the nozzle 310 reaches the substrate 300, which prevents the liquid metal 303 from penetrating the hole 302 due to its high surface tension.

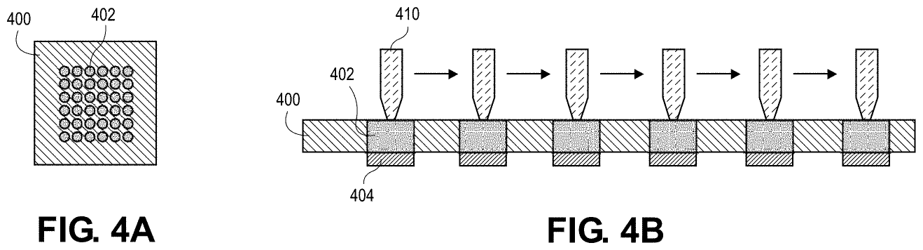

FIGS. 4A-B illustrate an example of using direct injection to fill a 6×6 substrate 400 with liquid metal. FIG. 4A shows a top view of the substrate 400, and FIG. 4B shows a cross-section view of the substrate 400 during the direct injection process. In the illustrated example, the substrate 400 includes a 6×6 array of holes 402 with caps 404 at the bottom to prevent leakage, and the holes 402 are sequentially filled with liquid metal via single needle 410 injection (e.g., one hole at a time).

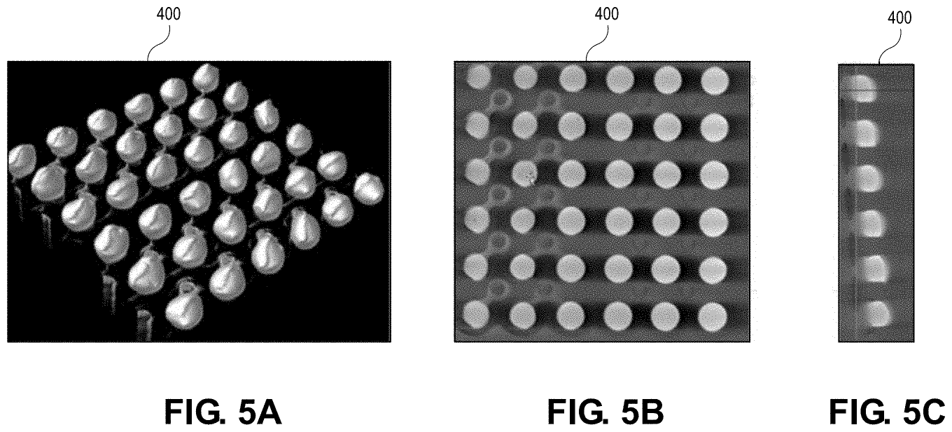

Example renderings of the liquid metal fill quality in the holes 402 of the substrate 400 are shown in FIGS. 5A-C, which respectively show isometric (FIG. 5A), top-down (FIG. 5B), and cross-section (FIG. 5C) views of the substrate 400 after performing direct injection.

These renderings depict good fill quality inside the holes, as the liquid metal is filled uniformly across the holes and remains in a pure liquid state with no voiding.

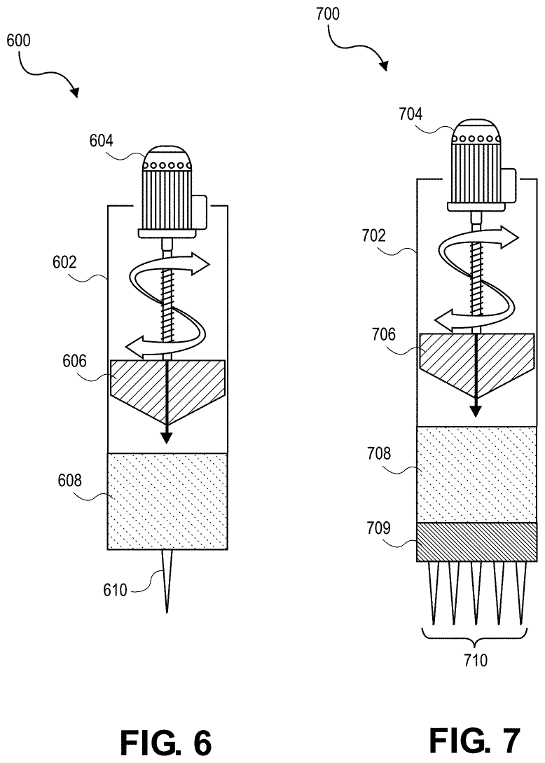

FIG. 6 illustrates an example embodiment of a direct injection filling tool 600. In the illustrated embodiment, the direct injection tool 600 includes a body 602, a head 604, a plunger 606 (e.g., a compression plate), a liquid metal reservoir 608, and a needle 610. The body 602 serves as a housing for the components in the tool 600. The liquid metal reservoir 608 is a container (also referred to as a barrel) for holding liquid metal or other liquids to be extruded by the direct injection tool 600. The head 604 provides control over the extrusion of liquid from the direct injection tool 600. For example, to extrude a particular volume of liquid metal, the head 604 exerts the appropriate amount of downward force on the plunger 606, which pushes the plunger 606 down and causes it to compress and squeeze liquid metal in the reservoir 608 through the hollow needle 610.

To inject liquid metal effectively, design parameters such as pressure, needle length, needle diameter, and tip design should be thoroughly evaluated and tuned for the particular application of the tool 600. There are several key considerations concerning injection head design and needle design.

For example, the injection tool 600 should have a robust head mechanism 604 with precise volume control and the ability to extrude highly viscous liquid metal. In the illustrated embodiment, the injection tool 600 includes a screw-driven type head 604. In other embodiments, however, the tool 600 may include any suitable type of head mechanism 604, such as a pressure-based pneumatic or hydraulic head mechanism, among other examples.

In some embodiments, the needle 610 is designed using the shortest length and largest gauge (e.g., diameter) possible, as longer dispenser tips and smaller gauges can cause unnecessary backpressure. The use of a shorter needle also reduces the cycle time. In some embodiments, the needle may include a tapered tip to reduce backpressure and turbulent flow in the syringe. Further, in some embodiments, the reservoir 608 and needle 610 include anti-corrosive protective material (e.g., metal, ceramic, or plastic) to prevent them from being corroded by the liquid metal.

FIG. 7 illustrates an example embodiment of a multi-needle direct injection tool 700. In the illustrated embodiment, the direct injection tool 700 is a single-head, single-reservoir, multi-needle device, which includes a body 702, a head 704, a plunger 706, a liquid metal reservoir 708, a modular needle array 709, and multiple needles 710.

In particular, to enhance the injectability and reduce cycle time, the direct injection tool 700 include multiple needles 710 instead of a single needle. While five needles 710 are shown in the illustrated embodiment, other embodiments may incorporate any suitable number of needles 710. For example, the needles 710 are incorporated on an interchangeable modular component 709, which may be referred to as a needle module, needle array module, or modular needle array, among other examples. Moreover, the needle array module 709 may be detachable, removable, pluggable, swappable, and/or otherwise interchangeable with other needle array modules 709 having different needle array configurations. For example, each needle array module 709 may have a particular needle array configuration, such as a particular number of needles, arrangement of needles in the array (e.g., one-dimensional (1D) versus two-dimensional (2D) needle array), needle length/diameter, tip design, needle spacing, and so forth.

In this manner, different needle array modules 709 can be used for different products or applications, which allows the needle configuration to be tailored to each particular application. As an example, the needle configuration can be tailored for direct injection of liquid metal in a substrate with a particular hole pattern.

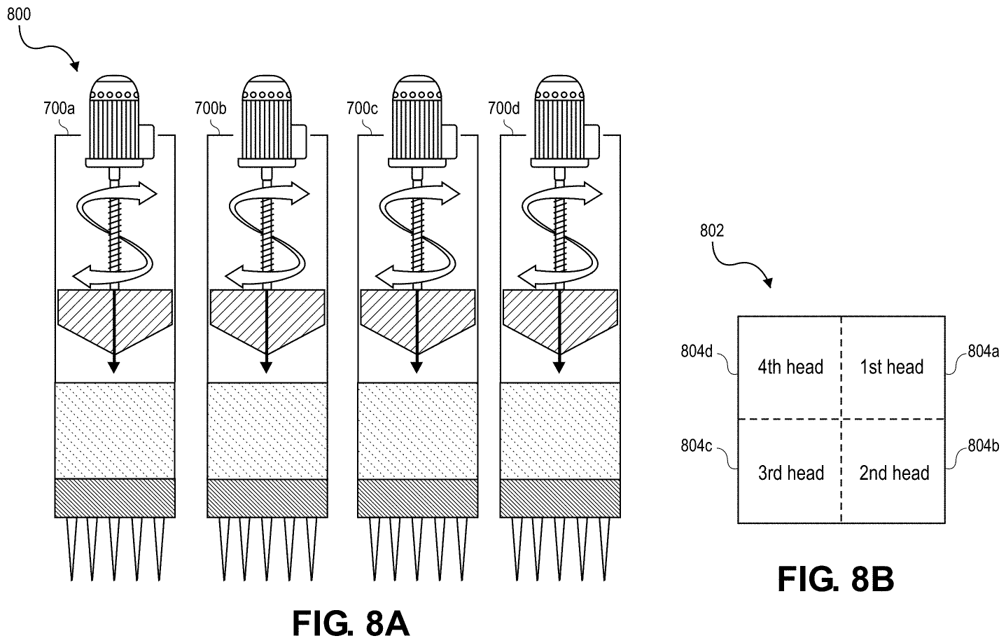

To reduce cycle time even further, multiple tools or heads can be incorporated into a direct injection system, as shown in FIGS. 8A-B.

FIGS. 8A-B illustrate an example embodiment of a multi-head direct injection system 800. FIG. 8A shows the direct injection system 800, and FIG. 8B shows an example of how the heads can be simultaneously used to fill holes in a substrate 802 to reduce cycle time. In the illustrated embodiment, the direct injection system 800 is a multi-head, multi-reservoir, multi-needle system. In particular, the direction injection system 800 includes multiple instances of the direct injection tool 700a-d from FIG. 7, each of which functions as an independent “head” 700a-d of the direct injection system 800.

In some embodiments, for example, each head 700a-d in the system 800 moves independently. For example, the heads 700a-d may be independently controlled by separate robotic arms, which enables each head 700a-d to move and dispense material independently from the others. This level of independence and autonomy is particularly beneficial for filling liquid metal into holes of a substrate 802 with a complicated hole pattern.

In the illustrated example, the substrate 802 is logically/conceptually partitioned into four sections or quadrants 804a-d, and each head 700a-d is responsible for filling the holes in one of the quadrants 804a-d. In this manner, multiple heads 700a-d are working together to simultaneously fill holes in different quadrants 804a-d of the substrate 802, which significantly reduces the cycle time. Moreover, for complex hole patterns, the respective heads 700a-d can have different modular needle arrays 709 with different needle configurations tailored to the hole patterns in their respective sections 804a-d of the substrate 802.

In addition, since each head 700a-d is fully independent, it has its own reservoir 708 and head/extrusion mechanism 704, which enables it to push any type or volume of viscous liquid into the holes with high precision. For example, different types of liquid metal or other materials can be injected into different sections 804a-d and holes of the substrate 802 with different patterns, where each head 700a-d is configured with the appropriate material in its reservoir 708, and the appropriate needle module 709 configuration, for the sections or holes filled by that head 700a-d.

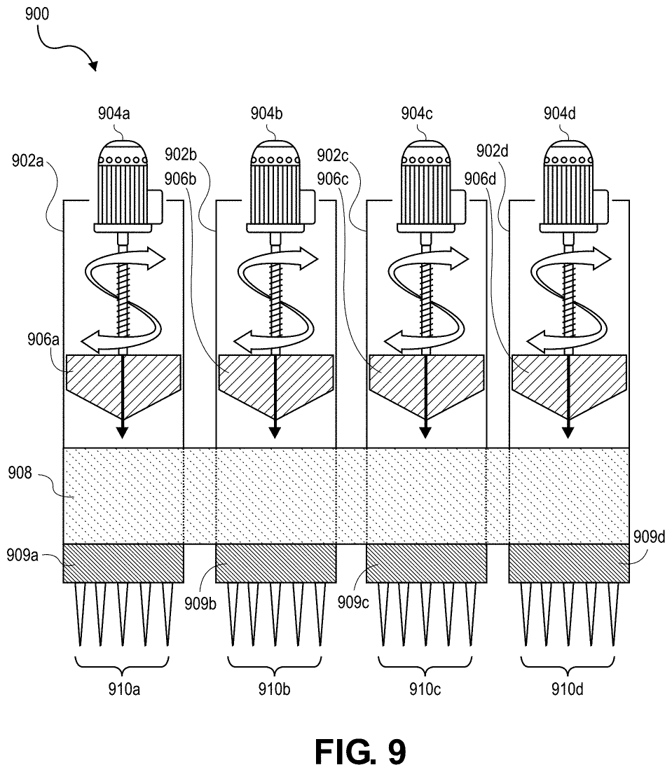

FIG. 9 illustrates an example embodiment of a multi-head single-reservoir direct injection system 900. The direct injection system 900 is similar to the system 800 of FIG. 8, except the heads 902a-d share the same liquid metal reservoir 908, and as a result, they cannot move independently. For example, the direct injection system 900 includes multiple bodies or “heads” 902a-d, along with multiple needles 910a-d per head, and each head 902a-d has its own extrusion mechanism 904a-d, plunger 906a-d, and needle module 909a-d. However, the direct injection system 900 has only one liquid metal reservoir 908, which is shared by the respective heads 902a-d. While this design prevents the heads 902a-d from moving independently, it allows an operator to fill liquid metal into the system reservoir 908 very quickly, which reduces unscheduled downtime when the reservoir 908 is empty.

While various embodiments of direct injection tools, devices, and systems have been shown and described herein (e.g., the direct injection embodiments of FIGS. 2 and 6-9), those embodiments are not limited to the particular configurations shown. For example, direction injection devices and systems can incorporate any number of direct injection tools or “heads,” any needle configuration on each head (whether modular or static) (e.g., number/spacing of needles, needle length/diameter, tip design), any suitable type of head extrusion mechanism (e.g., screw-driven head, pneumatic head, or hydraulic head), and any number of independent or shared reservoirs, among other examples.

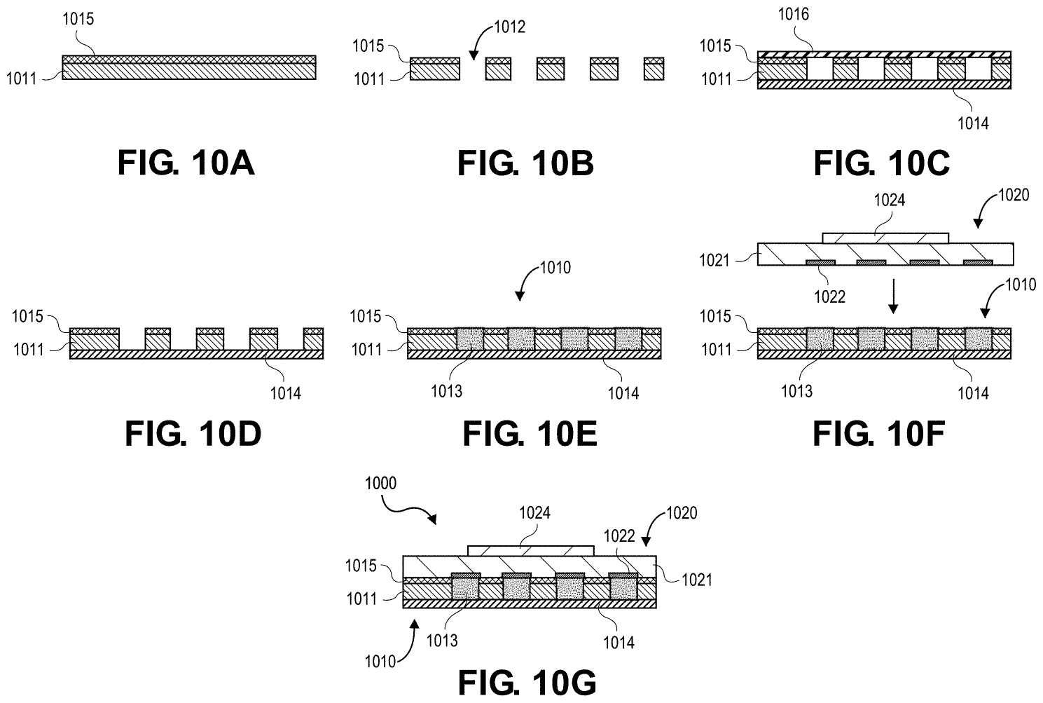

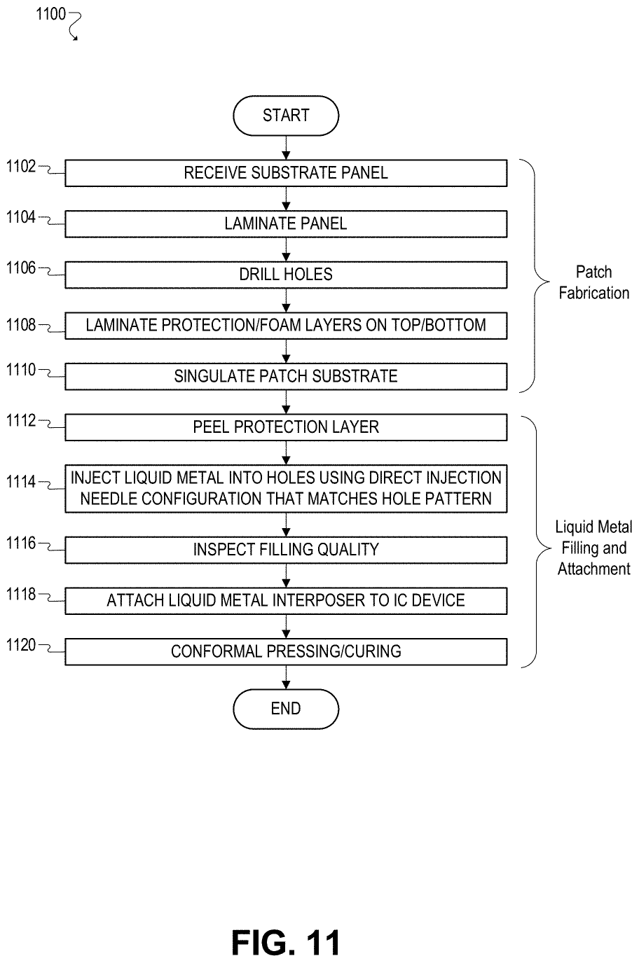

FIGS. 10A-G illustrate various stages of a manufacturing process for a socket-based integrated circuit (IC) package 1000 with a liquid metal interposer 1010 in accordance with certain embodiments. In addition, FIG. 11 illustrates a process flow 1100 for manufacturing the socket-based liquid metal IC package 1000 of FIGS. 10A-G. In the illustrated example, the socket-based liquid metal IC package 1000 includes an integrated circuit device 1020 packaged with a liquid metal interposer 1010, which is designed to interface with a socket. It will be appreciated in light of the present disclosure that process flow 1100 is only one example methodology for arriving at the liquid metal IC package 1000 of FIGS. 10A-G.

The steps of process flow 1100 may be performed using any suitable semiconductor fabrication techniques. For example, film deposition—such as depositing layers, filling portions of layers (e.g., removed portions), and filling via openings—may be performed using any suitable deposition techniques, including, for example, chemical vapor deposition (CVD), metalorganic chemical vapor deposition (MOCVD), molecular beam epitaxy (MBE) atomic layer deposition (ALD), and/or physical vapor deposition (PVD). Moreover, patterning and removal—such as interconnect patterning, forming via openings, and shaping—may be performed using any suitable techniques, such as lithography-based patterning/masking and/or etching.

Process flow 1100 is performed to manufacture the socket-based liquid metal integrated circuit (IC) package 1000 of FIGS. 10A-G. In particular, the socket-based liquid metal IC package 1000 includes an integrated circuit device 1020 packaged with a liquid metal interposer 1010, which is designed to interface with a socket.

The patch substrate 1010 for the liquid metal interposer “patch” is fabricated in blocks 1102-1110 of process flow 1100, and in blocks 1112-1120, liquid metal is filled in the holes 1012 of the patch substrate 1010 and the completed liquid metal “patch” 1010 is attached to an IC device 1020 to complete the IC package 1000.

In some embodiments, the patch manufacturing stage and liquid metal filling and attach stage may be performed separately (e.g., in different links of the supply chain and/or by different entities). For example, the patch manufacturing stage may be used to mass produce a large volume of unfilled patch substrates (e.g., with steps of panel lamination, mechanical drilling, top protection and bottom foam cap lamination, and singulation). The completed patch substrates may then be shipped or otherwise provided to other links in the supply chain (similar to typical substrates), where individual patch substrates may then be used to form integrated circuit packages.

For example, the liquid metal filling and attachment stage may be used to fill an individual patch substrate with liquid metal and attach the completed liquid metal patch to an integrated circuit device to form an integrated circuit package. Moreover, this stage may be performed in a single fully integrated link that includes the following steps: top side protection and liner peeling, liquid metal needle injection, metrology inspection, and final attach and curing.

The completed integrated circuit package will have a thin patch adhered to the bottom of the unit with liquid metal filled inside the holes. The bottom foam cap on the patch will seal the liquid metal to prevent leakage. The unit can then be inserted into a socket to form the electrical connection to power on. This provides a completely new second level interconnect (SLI) architecture, which is different from conventional land grid array (LGA), ball grid array (BGA), and pin grid array (PGA) technology.

The process flow begins at block 1102 by receiving a substrate panel 1011 (which will be used to fabricate multiple patch substrates for liquid metal interposers), and at block 1104, the panel 1011 is laminated with a thin laminate 1015, as shown in FIG. 10A.

At block 1106, holes 1012 are drilled in the laminated panel, as shown in FIG. 10B.

At block 1108, protection 1016 and foam 1014 layers are laminated on the top and bottom of the panel, respectively, as shown in FIG. 10C. For example, the protection layer 1016 is laminated on the top of the panel to provide temporary protection for the holes 1012 until they are ready to be filled with liquid metal. The foam layer 1014 is laminated on the bottom of the panel to prevent leakage after the holes 1012 have been filled with liquid metal.

At block 1110, the completed patch substrate panel (shown in FIG. 10C) is singulated into individual patch substrates.

At block 1112, the protection layer 1016 is peeled off an individual patch substrate, as shown in FIG. 10D.

At block 1114, liquid metal is injected into the holes 1012 in the patch substrate using a direct injection needle configuration that matches the pattern of holes in the substrate. Liquid metal needle direct injection is a core process step of this link and may be performed using the direct injection devices, systems, and methods described throughout this disclosure. The completed liquid metal interposer patch 1010 is shown in FIG. 10E.

At block 1116, the filling quality of the liquid metal is inspected. With inline metrology, filling defects can be flagged immediately for rework to increase final product yield and quality.

At block 1118, the completed liquid metal interposer “patch” 1010, and an integrated circuit device 1020, are pick-and-place attached to form an integrated circuit package, as shown in FIG. 10F. In some embodiments, for example, the integrated circuit device 1020 may be a microcontroller, microprocessor, processor core, central processing unit (CPU), graphics processing unit (GPU), vision processing unit (VPU), artificial intelligence/machine learning accelerator, field-programmable gate array (FPGA), memory device, or communication device (e.g., network interface controller (NIC), input/output (I/O) controller or hub), among other examples.

At block 1120, conformal pressing and curing is performed to complete the integrated circuit package 1000, which is shown in FIG. 10G.

At this point, the process flow may be complete. In some embodiments, however, the process flow may restart and/or certain blocks may be repeated. For example, in some embodiments, the process flow may restart at block 1102 to continue manufacturing another liquid metal integrated circuit package with the same or different design.

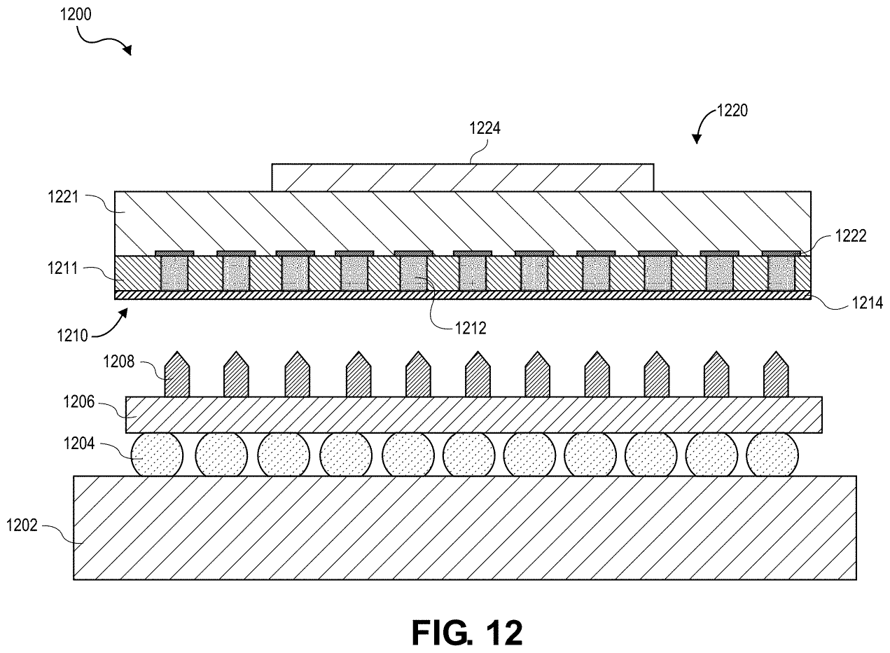

FIG. 12 illustrates an example embodiment of a liquid metal socket system 1200. In the illustrated embodiment, the liquid metal socket system 1200 includes a printed circuit board (PCB) 1202 (e.g., a motherboard), a socket 1206, a liquid metal interposer 1210, and a processor package 1220, as described below.

The socket substrate 1206 is attached to the PCB 1202 via a ball grid array 1204 and also includes pins 1208 designed to interface with the liquid metal interposer 1210.

The liquid metal interposer 1210 includes a patch substrate 1211 with a liquid metal interconnect 1212 formed in the holes of the substrate—which is designed to interface with the pins 1208 on the socket 1206—and a sealing cap 1214 to prevent leakage.

The processor package 1220 is an integrated circuit package that includes a package substrate 1221, contact pads 1222, and a processor die 1224.

The processor package 1220 and the liquid metal interposer 1210 are also packaged together (e.g., using the packaging process flow of FIGS. 10A-G and 11), which collectively form a liquid metal socket interface package. In particular, the contacts pads 1222 in the processor package 1220 are electrically coupled with the liquid metal interconnect 1212 in the interposer 1210.

In this manner, the liquid metal interposer 1210 enables the processor package 1220 to interface with the socket 1206, and by extension, with the PCB 1202. This socket design only requires force to penetrate the cap 1214 on the liquid metal interposer 1210. However, no high loading force is needed to ensure the socket pins 1208 can contact the processor pads 1222 since the liquid metal serves as a conductive medium between the pins 1208 and pads 1222. As a result, this liquid metal socket design eliminates loading complexity and enables pin count scaling without the need for the higher loads (unlike land grid array (LGA) socket technology).

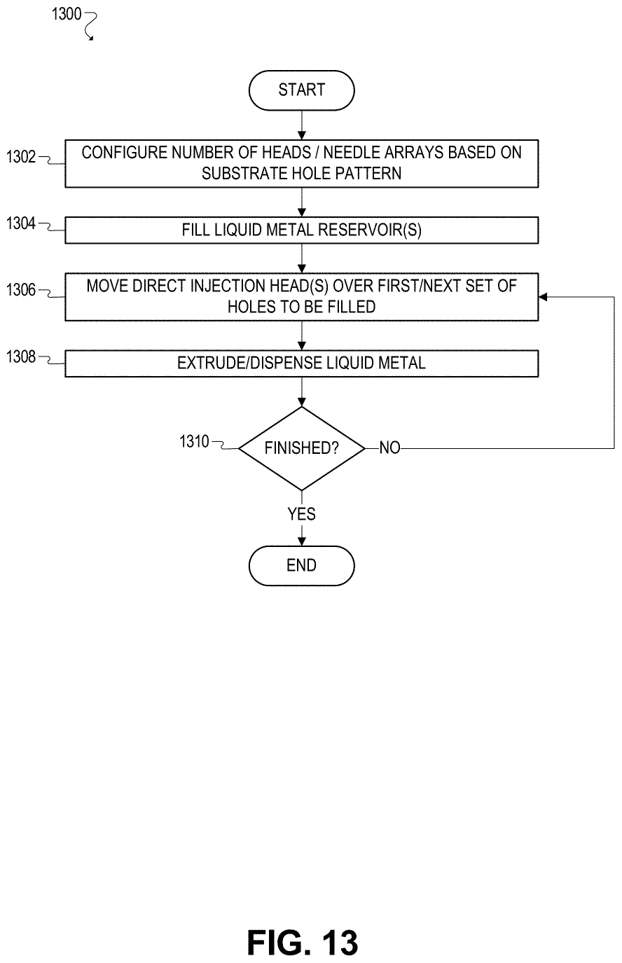

FIG. 13 illustrates a flowchart 1300 for forming a liquid metal interconnect using a direct injection system in accordance with certain embodiments. In some embodiments, for example, flowchart 1300 may be performed using the direct injection devices and systems described throughout this disclosure.

The flowchart begins at block 1302 by configuring the number of heads in the direct injection system, and the needle array on each head, based on the hole pattern in the substrate that needs to be filled. In particular, each head of the direct injection system may be outfitted with a modular needle array having a configuration that matches the hole array to be filled by that head. For example, the modular needle array may have a particular number of needles, arrangement of needles (e.g., number of rows/columns of needles, spacing of needles), needle length, diameter, tip design, and so forth.

The flowchart then proceeds to block 1304 to fill the reservoir in the system with liquid metal.

The flowchart then proceeds to block 1306 to move the direct injection head(s), and their associated needle array(s), over the first set of holes to be filled, with the needles in close proximity to the holes.

The flowchart then proceeds to block 1308 to cause each head to extrude/dispense liquid metal from its associated needle array into the holes. For example, each head dispenses the precise volume of liquid metal required to fill the holes positioned directly below its needle array.

The flowchart then proceeds to block 1310 to determine if all holes have been filed. If there are still additional holes to fill, the flowchart repeats blocks 1306-1308 to move the direct injection head(s) over the next set of holes to be filled and extrude liquid metal into those holes. The flowchart continues cycling through blocks 1306-1308 in this manner until determining at block 1310 that all holes have been filed.

At this point, the flowchart may be complete. In some embodiments, however, the flowchart may restart and/or certain blocks may be repeated. For example, in some embodiments, the flowchart may restart at block 1302 to continue forming another liquid metal interconnect with the same or different hole pattern.

### Example Integrated Circuit Embodiments

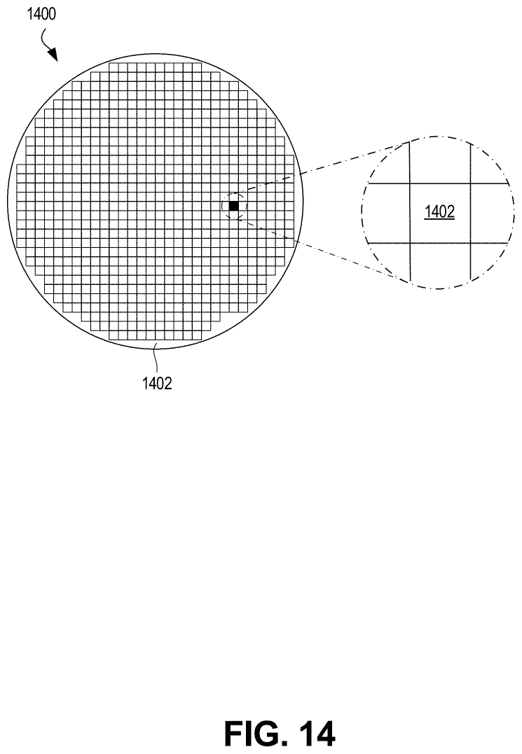

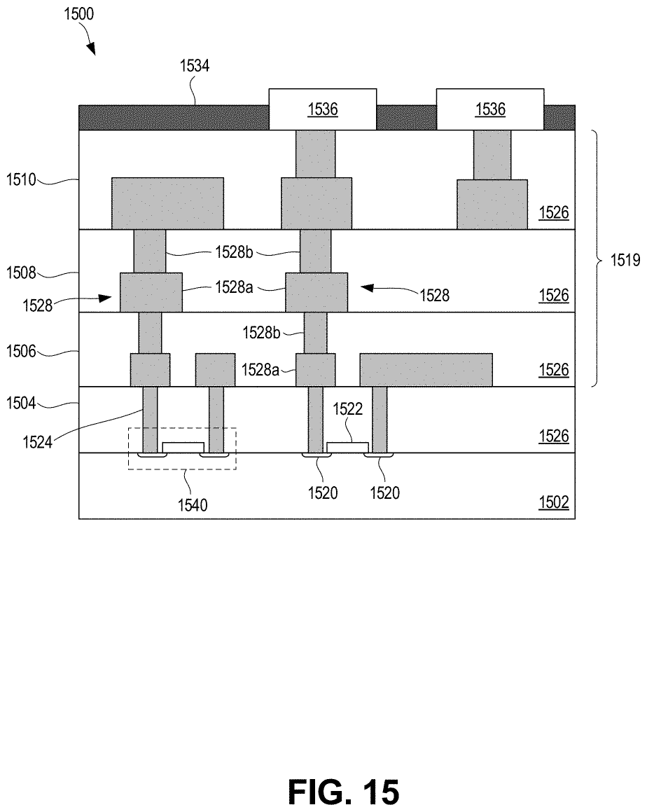

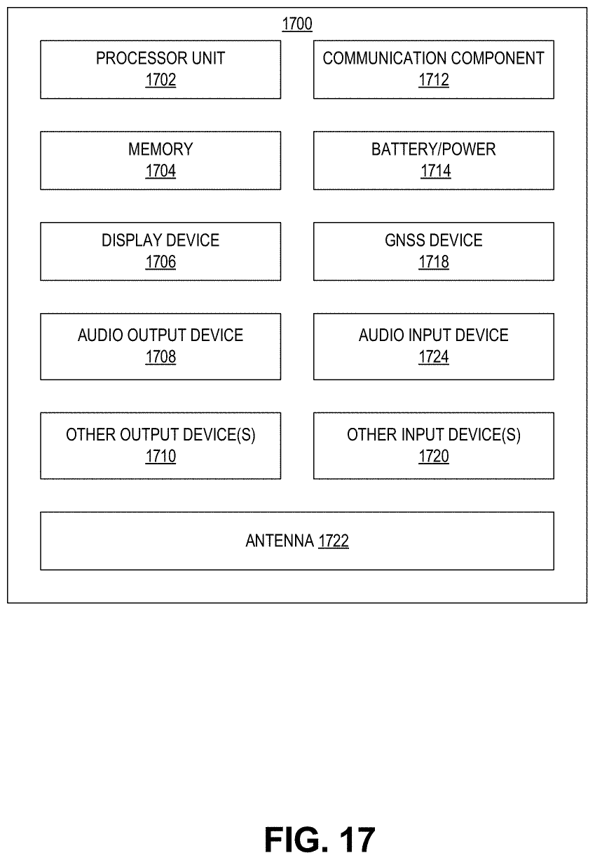

FIG. 14 is a top view of a wafer 1400 and dies 1402 that may be included in any of the embodiments disclosed herein. The wafer 1400 may be composed of semiconductor material and may include one or more dies 1402 having integrated circuit structures formed on a surface of the wafer 1400. The individual dies 1402 may be a repeating unit of an integrated circuit product that includes any suitable integrated circuit. After the fabrication of the semiconductor product is complete, the wafer 1400 may undergo a singulation process in which the dies 1402 are separated from one another to provide discrete “chips” of the integrated circuit product. The die 1402 may be any of the dies disclosed herein. The die 1402 may include one or more transistors (e.g., some of the transistors 1540 of FIG. 15, discussed below), supporting circuitry to route electrical signals to the transistors, passive components (e.g., signal traces, resistors, capacitors, or inductors), and/or any other integrated circuit components. In some embodiments, the wafer 1400 or the die 1402 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 1402. For example, a memory array formed by multiple memory devices may be formed on a same die 1402 as a processor unit (e.g., the processor unit 1702 of FIG. 17) or other logic that is configured to store information in the memory devices or execute instructions stored in the memory array. Various ones of the microelectronic assemblies disclosed herein may be manufactured using a die-to-wafer assembly technique in which some dies are attached to a wafer 1400 that include others of the dies, and the wafer 1400 is subsequently singulated.

FIG. 15 is a cross-sectional side view of an integrated circuit device 1500 that may be included in any of the embodiments disclosed herein (e.g., in any of the dies). One or more of the integrated circuit devices 1500 may be included in one or more dies 1402 (FIG. 14). The integrated circuit device 1500 may be formed on a die substrate 1502 (e.g., the wafer 1400 of FIG. 14) and may be included in a die (e.g., the die 1402 of FIG. 14). The die substrate 1502 may be a semiconductor substrate composed of semiconductor material systems including, for example, n-type or p-type materials systems (or a combination of both). The die substrate 1502 may include, for example, a crystalline substrate formed using a bulk silicon or a silicon-on-insulator (SOI) substructure. In some embodiments, the die substrate 1502 may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI, III-V, or IV may also be used to form the die substrate 1502. Although a few examples of materials from which the die substrate 1502 may be formed are described here, any material that may serve as a foundation for an integrated circuit device 1500 may be used. The die substrate 1502 may be part of a singulated die (e.g., the dies 1402 of FIG. 14) or a wafer (e.g., the wafer 1400 of FIG. 14).

The integrated circuit device 1500 may include one or more device layers 1504 disposed on the die substrate 1502. The device layer 1504 may include features of one or more transistors 1540 (e.g., metal oxide semiconductor field-effect transistors (MOSFETs)) formed on the die substrate 1502. The transistors 1540 may include, for example, one or more source and/or drain (S/D) regions 1520, a gate 1522 to control current flow between the S/D regions 1520, and one or more S/D contacts 1524 to route electrical signals to/from the S/D regions 1520. The transistors 1540 may include additional features not depicted for the sake of clarity, such as device isolation regions, gate contacts, and the like. The transistors 1540 are not limited to the type and configuration depicted in FIG. 15 and may include a wide variety of other types and configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon, nanosheet, or nanowire transistors.

Returning to FIG. 15, a transistor 1540 may include a gate 1522 formed of at least two layers, a gate dielectric and a gate electrode. The gate dielectric may include one layer or a stack of layers. The one or more layers may include silicon oxide, silicon dioxide, silicon carbide, and/or a high-k dielectric material.

The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric to improve its quality when a high-k material is used.

The gate electrode may be formed on the gate dielectric and may include at least one p-type work function metal or n-type work function metal, depending on whether the transistor 1540 is to be a p-type metal oxide semiconductor (PMOS) or an n-type metal oxide semiconductor (NMOS) transistor. In some implementations, the gate electrode may consist of a stack of two or more metal layers, where one or more metal layers are work function metal layers and at least one metal layer is a fill metal layer. Further metal layers may be included for other purposes, such as a barrier layer.

For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, when viewed as a cross-section of the transistor 1540 along the source-channel-drain direction, the gate electrode may consist of a U-shaped structure that includes a bottom portion substantially parallel to the surface of the die substrate 1502 and two sidewall portions that are substantially perpendicular to the top surface of the die substrate 1502. In other embodiments, at least one of the metal layers that form the gate electrode may simply be a planar layer that is substantially parallel to the top surface of the die substrate 1502 and does not include sidewall portions substantially perpendicular to the top surface of the die substrate 1502. In other embodiments, the gate electrode may consist of a combination of U-shaped structures and planar, non-U-shaped structures. For example, the gate electrode may consist of one or more U-shaped metal layers formed atop one or more planar, non-U-shaped layers.

In some embodiments, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some embodiments, a plurality of spacer pairs may be used; for instance, two pairs, three pairs, or four pairs of sidewall spacers may be formed on opposing sides of the gate stack.

The S/D regions 1520 may be formed within the die substrate 1502 adjacent to the gate 1522 of individual transistors 1540. The S/D regions 1520 may be formed using an implantation/diffusion process or an etching/deposition process, for example. In the former process, dopants such as boron, aluminum, antimony, phosphorous, or arsenic may be ion-implanted into the die substrate 1502 to form the S/D regions 1520. An annealing process that activates the dopants and causes them to diffuse farther into the die substrate 1502 may follow the ion-implantation process. In the latter process, the die substrate 1502 may first be etched to form recesses at the locations of the S/D regions 1520. An epitaxial deposition process may then be carried out to fill the recesses with material that is used to fabricate the S/D regions 1520. In some implementations, the S/D regions 1520 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 1520 may be formed using one or more alternate semiconductor materials such as germanium or a group III-V material or alloy. In further embodiments, one or more layers of metal and/or metal alloys may be used to form the S/D regions 1520.

Electrical signals, such as power and/or input/output (I/O) signals, may be routed to and/or from the devices (e.g., transistors 1540) of the device layer 1504 through one or more interconnect layers disposed on the device layer 1504 (illustrated in FIG. 15 as interconnect layers 1506-1510). For example, electrically conductive features of the device layer 1504 (e.g., the gate 1522 and the S/D contacts 1524) may be electrically coupled with the interconnect structures 1528 of the interconnect layers 1506-1510. The one or more interconnect layers 1506-1510 may form a metallization stack (also referred to as an “ILD stack”) 1519 of the integrated circuit device 1500.

The interconnect structures 1528 may be arranged within the interconnect layers 1506-1510 to route electrical signals according to a wide variety of designs; in particular, the arrangement is not limited to the particular configuration of interconnect structures 1528 depicted in FIG. 15. Although a particular number of interconnect layers 1506-1510 is depicted in FIG. 15, embodiments of the present disclosure include integrated circuit devices having more or fewer interconnect layers than depicted.

In some embodiments, the interconnect structures 1528 may include lines 1528a and/or vias 1528b filled with an electrically conductive material such as a metal. The lines 1528a may be arranged to route electrical signals in a direction of a plane that is substantially parallel with a surface of the die substrate 1502 upon which the device layer 1504 is formed. For example, the lines 1528a may route electrical signals in a direction in and out of the page and/or in a direction across the page from the perspective of FIG. 15. The vias 1528b may be arranged to route electrical signals in a direction of a plane that is substantially perpendicular to the surface of the die substrate 1502 upon which the device layer 1504 is formed. In some embodiments, the vias 1528b may electrically couple lines 1528a of different interconnect layers 1506-1510 together.

The interconnect layers 1506-1510 may include a dielectric material 1526 disposed between the interconnect structures 1528, as shown in FIG. 15. In some embodiments, dielectric material 1526 disposed between the interconnect structures 1528 in different ones of the interconnect layers 1506-1510 may have different compositions; in other embodiments, the composition of the dielectric material 1526 between different interconnect layers 1506-1510 may be the same. The device layer 1504 may include a dielectric material 1526 disposed between the transistors 1540 and a bottom layer of the metallization stack as well. The dielectric material 1526 included in the device layer 1504 may have a different composition than the dielectric material 1526 included in the interconnect layers 1506-1510; in other embodiments, the composition of the dielectric material 1526 in the device layer 1504 may be the same as a dielectric material 1526 included in any one of the interconnect layers 1506-1510.

A first interconnect layer 1506 (referred to as Metal 1 or “M1”) may be formed directly on the device layer 1504. In some embodiments, the first interconnect layer 1506 may include lines 1528a and/or vias 1528b, as shown. The lines 1528a of the first interconnect layer 1506 may be coupled with contacts (e.g., the S/D contacts 1524) of the device layer 1504. The vias 1528b of the first interconnect layer 1506 may be coupled with the lines 1528a of a second interconnect layer 1508.

The second interconnect layer 1508 (referred to as Metal 2 or “M2”) may be formed directly on the first interconnect layer 1506. In some embodiments, the second interconnect layer 1508 may include via 1528b to couple the lines 1528 of the second interconnect layer 1508 with the lines 1528a of a third interconnect layer 1510. Although the lines 1528a and the vias 1528b are structurally delineated with a line within individual interconnect layers for the sake of clarity, the lines 1528a and the vias 1528b may be structurally and/or materially contiguous (e.g., simultaneously filled during a dual-damascene process) in some embodiments.

The third interconnect layer 1510 (referred to as Metal 3 or “M3”) (and additional interconnect layers, as desired) may be formed in succession on the second interconnect layer 1508 according to similar techniques and configurations described in connection with the second interconnect layer 1508 or the first interconnect layer 1506. In some embodiments, the interconnect layers that are “higher up” in the metallization stack 1519 in the integrated circuit device 1500 (i.e., farther away from the device layer 1504) may be thicker that the interconnect layers that are lower in the metallization stack 1519, with lines 1528a and vias 1528b in the higher interconnect layers being thicker than those in the lower interconnect layers.

The integrated circuit device 1500 may include a solder resist material 1534 (e.g., polyimide or similar material) and one or more conductive contacts 1536 formed on the interconnect layers 1506-1510. In FIG. 15, the conductive contacts 1536 are illustrated as taking the form of bond pads. The conductive contacts 1536 may be electrically coupled with the interconnect structures 1528 and configured to route the electrical signals of the transistor(s) 1540 to external devices. For example, solder bonds may be formed on the one or more conductive contacts 1536 to mechanically and/or electrically couple an integrated circuit die including the integrated circuit device 1500 with another component (e.g., a printed circuit board). The integrated circuit device 1500 may include additional or alternate structures to route the electrical signals from the interconnect layers 1506-1510; for example, the conductive contacts 1536 may include other analogous features (e.g., posts) that route the electrical signals to external components. The conductive contacts 1536 may serve as any of the conductive contacts described throughout this disclosure.

In some embodiments in which the integrated circuit device 1500 is a double-sided die, the integrated circuit device 1500 may include another metallization stack (not shown) on the opposite side of the device layer(s) 1504. This metallization stack may include multiple interconnect layers as discussed above with reference to the interconnect layers 1506-1510, to provide conductive pathways (e.g., including conductive lines and vias) between the device layer(s) 1504 and additional conductive contacts (not shown) on the opposite side of the integrated circuit device 1500 from the conductive contacts 1536. These additional conductive contacts may serve as any of the conductive contacts described throughout this disclosure.

In other embodiments in which the integrated circuit device 1500 is a double-sided die, the integrated circuit device 1500 may include one or more through silicon vias (TSVs) through the die substrate 1502; these TSVs may make contact with the device layer(s) 1504, and may provide conductive pathways between the device layer(s) 1504 and additional conductive contacts (not shown) on the opposite side of the integrated circuit device 1500 from the conductive contacts 1536. These additional conductive contacts may serve as any of the conductive contacts described throughout this disclosure. In some embodiments, TSVs extending through the substrate can be used for routing power and ground signals from conductive contacts on the opposite side of the integrated circuit device 1500 from the conductive contacts 1536 to the transistors 1540 and any other components integrated into the die 1500, and the metallization stack 1519 can be used to route I/O signals from the conductive contacts 1536 to transistors 1540 and any other components integrated into the die 1500.

Multiple integrated circuit devices 1500 may be stacked with one or more TSVs in the individual stacked devices providing connection between one of the devices to any of the other devices in the stack. For example, one or more high-bandwidth memory (HBM) integrated circuit dies can be stacked on top of a base integrated circuit die and TSVs in the HBM dies can provide connection between the individual HBM and the base integrated circuit die. Conductive contacts can provide additional connections between adjacent integrated circuit dies in the stack. In some embodiments, the conductive contacts can be fine-pitch solder bumps (microbumps).

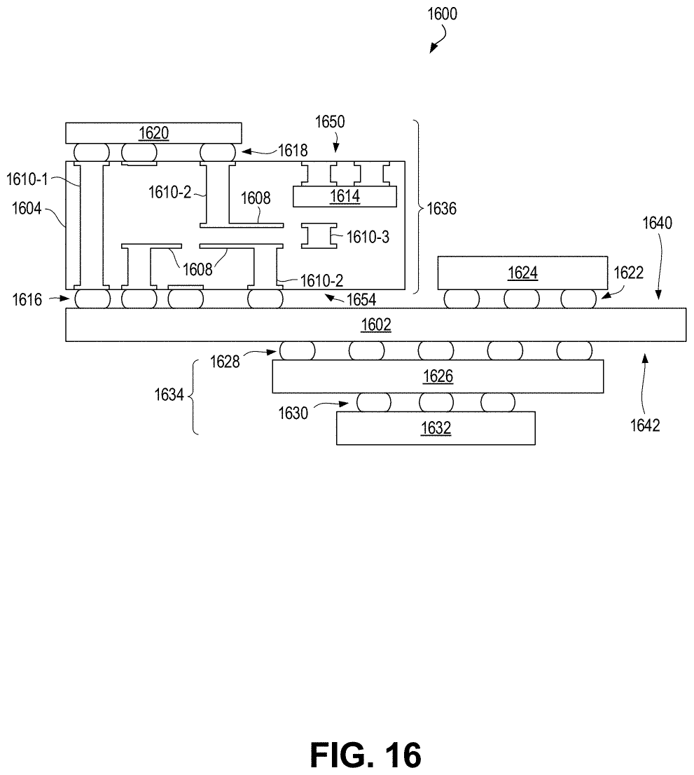

FIG. 16 is a cross-sectional side view of an integrated circuit device assembly 1600 that may include any of the embodiments disclosed herein. In some embodiments, the integrated circuit device assembly 1600 may be a microelectronic assembly. The integrated circuit device assembly 1600 includes a number of components disposed on a circuit board 1602 (which may be a motherboard, system board, mainboard, etc.). The integrated circuit device assembly 1600 includes components disposed on a first face 1640 of the circuit board 1602 and an opposing second face 1642 of the circuit board 1602; generally, components may be disposed on one or both faces 1640 and 1642. Any of the integrated circuit components discussed below with reference to the integrated circuit device assembly 1600 may take the form of any suitable ones of the embodiments of the microelectronic assemblies disclosed herein (e.g., liquid metal-based interconnects, interposers, and/or socket interfaces).

In some embodiments, the circuit board 1602 may be a printed circuit board (PCB) including multiple metal (or interconnect) layers separated from one another by layers of dielectric material and interconnected by electrically conductive vias. The individual metal layers comprise conductive traces. Any one or more of the metal layers may be formed in a desired circuit pattern to route electrical signals (optionally in conjunction with other metal layers) between the components coupled to the circuit board 1602. In other embodiments, the circuit board 1602 may be a non-PCB substrate. The integrated circuit device assembly 1600 illustrated in FIG. 16 includes a package-on-interposer structure 1636 coupled to the first face 1640 of the circuit board 1602 by coupling components 1616. The coupling components 1616 may electrically and mechanically couple the package-on-interposer structure 1636 to the circuit board 1602, and may include solder balls (as shown in FIG. 16), pins (e.g., as part of a pin grid array (PGA), contacts (e.g., as part of a land grid array (LGA)), male and female portions of a socket, an adhesive, an underfill material, and/or any other suitable electrical and/or mechanical coupling structure. The coupling components 1616 may serve as the coupling components illustrated or described for any of the substrate assembly or substrate assembly components described herein, as appropriate.

The package-on-interposer structure 1636 may include an integrated circuit component 1620 coupled to an interposer 1604 by coupling components 1618. The coupling components 1618 may take any suitable form for the application, such as the forms discussed above with reference to the coupling components 1616. Although a single integrated circuit component 1620 is shown in FIG. 16, multiple integrated circuit components may be coupled to the interposer 1604; indeed, additional interposers may be coupled to the interposer 1604. The interposer 1604 may provide an intervening substrate used to bridge the circuit board 1602 and the integrated circuit component 1620.

The integrated circuit component 1620 may be a packaged or unpacked integrated circuit product that includes one or more integrated circuit dies (e.g., the die 1402 of FIG. 14, the integrated circuit device 1500 of FIG. 15) and/or one or more other suitable components. A packaged integrated circuit component comprises one or more integrated circuit dies mounted on a package substrate with the integrated circuit dies and package substrate encapsulated in a casing material, such as a metal, plastic, glass, or ceramic. In one example of an unpackaged integrated circuit component 1620, a single monolithic integrated circuit die comprises solder bumps attached to contacts on the die. The solder bumps allow the die to be directly attached to the interposer 1604. The integrated circuit component 1620 can comprise one or more computing system components, such as one or more processor units (e.g., system-on-a-chip (SoC), processor core, graphics processor unit (GPU), accelerator, chipset processor), I/O controller, memory, or network interface controller. In some embodiments, the integrated circuit component 1620 can comprise one or more additional active or passive devices such as capacitors, decoupling capacitors, resistors, inductors, fuses, diodes, transformers sensors, electrostatic discharge (ESD) devices, and memory devices.

In embodiments where the integrated circuit component 1620 comprises multiple integrated circuit dies, they dies can be of the same type (a homogeneous multi-die integrated circuit component) or of two or more different types (a heterogeneous multi-die integrated circuit component). A multi-die integrated circuit component can be referred to as a multi-chip package (MCP) or multi-chip module (MCM).

In addition to comprising one or more processor units, the integrated circuit component 1620 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. These separate integrated circuit dies can be referred to as “chiplets”. In embodiments where an integrated circuit component comprises multiple integrated circuit dies, interconnections between dies can be provided by the package substrate, one or more silicon interposers, one or more silicon bridges embedded in the package substrate (such as Intel® embedded multi-die interconnect bridges (EMIBs)), or combinations thereof.

Generally, the interposer 1604 may spread connections to a wider pitch or reroute a connection to a different connection. For example, the interposer 1604 may couple the integrated circuit component 1620 to a set of ball grid array (BGA) conductive contacts of the coupling components 1616 for coupling to the circuit board 1602. In the embodiment illustrated in FIG. 16, the integrated circuit component 1620 and the circuit board 1602 are attached to opposing sides of the interposer 1604; in other embodiments, the integrated circuit component 1620 and the circuit board 1602 may be attached to a same side of the interposer 1604. In some embodiments, three or more components may be interconnected by way of the interposer 1604.

In some embodiments, the interposer 1604 may be formed as a PCB, including multiple metal layers separated from one another by layers of dielectric material and interconnected by electrically conductive vias. In some embodiments, the interposer 1604 may be formed of an epoxy resin, a fiberglass-reinforced epoxy resin, an epoxy resin with inorganic fillers, a ceramic material, or a polymer material such as polyimide. In some embodiments, the interposer 1604 may be formed of alternate rigid or flexible materials that may include the same materials described above for use in a semiconductor substrate, such as silicon, germanium, and other group III-V and group IV materials. The interposer 1604 may include metal interconnects 1608 and vias 1610, including but not limited to through hole vias 1610-1 (that extend from a first face 1650 of the interposer 1604 to a second face 1654 of the interposer 1604), blind vias 1610-2 (that extend from the first or second faces 1650 or 1654 of the interposer 1604 to an internal metal layer), and buried vias 1610-3 (that connect internal metal layers).

In some embodiments, the interposer 1604 can comprise a silicon interposer. Through silicon vias (TSV) extending through the silicon interposer can connect connections on a first face of a silicon interposer to an opposing second face of the silicon interposer. In some embodiments, an interposer 1604 comprising a silicon interposer can further comprise one or more routing layers to route connections on a first face of the interposer 1604 to an opposing second face of the interposer 1604.

The interposer 1604 may further include embedded devices 1614, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 1604. The package-on-interposer structure 1636 may take the form of any of the package-on-interposer structures known in the art. In embodiments where the interposer is a non-printed circuit board

The integrated circuit device assembly 1600 may include an integrated circuit component 1624 coupled to the first face 1640 of the circuit board 1602 by coupling components 1622. The coupling components 1622 may take the form of any of the embodiments discussed above with reference to the coupling components 1616, and the integrated circuit component 1624 may take the form of any of the embodiments discussed above with reference to the integrated circuit component 1620.

The integrated circuit device assembly 1600 illustrated in FIG. 16 includes a package-on-package structure 1634 coupled to the second face 1642 of the circuit board 1602 by coupling components 1628. The package-on-package structure 1634 may include an integrated circuit component 1626 and an integrated circuit component 1632 coupled together by coupling components 1630 such that the integrated circuit component 1626 is disposed between the circuit board 1602 and the integrated circuit component 1632. The coupling components 1628 and 1630 may take the form of any of the embodiments of the coupling components 1616 discussed above, and the integrated circuit components 1626 and 1632 may take the form of any of the embodiments of the integrated circuit component 1620 discussed above. The package-on-package structure 1634 may be configured in accordance with any of the package-on-package structures known in the art.

FIG. 17 is a block diagram of an example electrical device 1700 that may include one or more of the embodiments disclosed herein. For example, any suitable ones of the components of the electrical device 1700 may include one or more of the liquid metal (LM) interconnects (e.g., LM interposers and/or socket interfaces), integrated circuit device assemblies 1600, integrated circuit components 1620, integrated circuit devices 1500, or integrated circuit dies 1402 disclosed herein. A number of components are illustrated in FIG. 17 as included in the electrical device 1700, but any one or more of these components may be omitted or duplicated, as suitable for the application. In some embodiments, some or all of the components included in the electrical device 1700 may be attached to one or more motherboards mainboards, or system boards. In some embodiments, one or more of these components are fabricated onto a single system-on-a-chip (SoC) die.

Additionally, in various embodiments, the electrical device 1700 may not include one or more of the components illustrated in FIG. 17, but the electrical device 1700 may include interface circuitry for coupling to the one or more components. For example, the electrical device 1700 may not include a display device 1706, but may include display device interface circuitry (e.g., a connector and driver circuitry) to which a display device 1706 may be coupled. In another set of examples, the electrical device 1700 may not include an audio input device 1724 or an audio output device 1708, but may include audio input or output device interface circuitry (e.g., connectors and supporting circuitry) to which an audio input device 1724 or audio output device 1708 may be coupled.

The electrical device 1700 may include one or more processor units 1702 (e.g., one or more processor units). As used herein, the terms “processor unit”, “processing unit” or “processor” may refer to any device or portion of a device that processes electronic data from registers and/or memory to transform that electronic data into other electronic data that may be stored in registers and/or memory. The processor unit 1702 may include one or more digital signal processors (DSPs), application-specific integrated circuits (ASICs), central processing units (CPUs), graphics processing units (GPUs), general-purpose GPUs (GPGPUs), accelerated processing units (APUs), field-programmable gate arrays (FPGAs), neural network processing units (NPUs), data processor units (DPUs), accelerators (e.g., graphics accelerator, compression accelerator, artificial intelligence accelerator), controller cryptoprocessors (specialized processors that execute cryptographic algorithms within hardware), server processors, controllers, or any other suitable type of processor units. As such, the processor unit can be referred to as an XPU (or xPU).

The electrical device 1700 may include a memory 1704, which may itself include one or more memory devices such as volatile memory (e.g., dynamic random access memory (DRAM), static random-access memory (SRAM)), non-volatile memory (e.g., read-only memory (ROM), flash memory, chalcogenide-based phase-change non-voltage memories), solid state memory, and/or a hard drive. In some embodiments, the memory 1704 may include memory that is located on the same integrated circuit die as the processor unit 1702. This memory may be used as cache memory (e.g., Level 1 (L1), Level 2 (L2), Level 3 (L3), Level 4 (L4), Last Level Cache (LLC)) and may include embedded dynamic random access memory (eDRAM) or spin transfer torque magnetic random access memory (STT-MRAM).

In some embodiments, the electrical device 1700 can comprise one or more processor units 1702 that are heterogeneous or asymmetric to another processor unit 1702 in the electrical device 1700. There can be a variety of differences between the processing units 1702 in a system in terms of a spectrum of metrics of merit including architectural, microarchitectural, thermal, power consumption characteristics, and the like. These differences can effectively manifest themselves as asymmetry and heterogeneity among the processor units 1702 in the electrical device 1700.

In some embodiments, the electrical device 1700 may include a communication component 1712 (e.g., one or more communication components). For example, the communication component 1712 can manage wireless communications for the transfer of data to and from the electrical device 1700. The term “wireless” and its derivatives may be used to describe circuits, devices, systems, methods, techniques, communications channels, etc., that may communicate data through the use of modulated electromagnetic radiation through a nonsolid medium. The term “wireless” does not imply that the associated devices do not contain any wires, although in some embodiments they might not.

The communication component 1712 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication component 1712 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication component 1712 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication component 1712 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication component 1712 may operate in accordance with other wireless protocols in other embodiments. The electrical device 1700 may include an antenna 1722 to facilitate wireless communications and/or to receive other wireless communications (such as AM or FM radio transmissions).

In some embodiments, the communication component 1712 may manage wired communications, such as electrical, optical, or any other suitable communication protocols (e.g., IEEE 802.3 Ethernet standards). As noted above, the communication component 1712 may include multiple communication components. For instance, a first communication component 1712 may be dedicated to shorter-range wireless communications such as Wi-Fi or Bluetooth, and a second communication component 1712 may be dedicated to longer-range wireless communications such as global positioning system (GPS), EDGE, GPRS, CDMA, WiMAX, LTE, EV-DO, or others. In some embodiments, a first communication component 1712 may be dedicated to wireless communications, and a second communication component 1712 may be dedicated to wired communications.

The electrical device 1700 may include battery/power circuitry 1714. The battery/power circuitry 1714 may include one or more energy storage devices (e.g., batteries or capacitors) and/or circuitry for coupling components of the electrical device 1700 to an energy source separate from the electrical device 1700 (e.g., AC line power).

The electrical device 1700 may include a display device 1706 (or corresponding interface circuitry, as discussed above). The display device 1706 may include one or more embedded or wired or wirelessly connected external visual indicators, such as a heads-up display, a computer monitor, a projector, a touchscreen display, a liquid crystal display (LCD), a light-emitting diode display, or a flat panel display.

The electrical device 1700 may include an audio output device 1708 (or corresponding interface circuitry, as discussed above). The audio output device 1708 may include any embedded or wired or wirelessly connected external device that generates an audible indicator, such speakers, headsets, or earbuds.

The electrical device 1700 may include an audio input device 1724 (or corresponding interface circuitry, as discussed above). The audio input device 1724 may include any embedded or wired or wirelessly connected device that generates a signal representative of a sound, such as microphones, microphone arrays, or digital instruments (e.g., instruments having a musical instrument digital interface (MIDI) output). The electrical device 1700 may include a Global Navigation Satellite System (GNSS) device 1718 (or corresponding interface circuitry, as discussed above), such as a Global Positioning System (GPS) device. The GNSS device 1718 may be in communication with a satellite-based system and may determine a geolocation of the electrical device 1700 based on information received from one or more GNSS satellites, as known in the art.

The electrical device 1700 may include other output device(s) 1710 (or corresponding interface circuitry, as discussed above). Examples of the other output device(s) 1710 may include an audio codec, a video codec, a printer, a wired or wireless transmitter for providing information to other devices, or an additional storage device.

The electrical device 1700 may include other input device(s) 1720 (or corresponding interface circuitry, as discussed above). Examples of the other input device(s) 1720 may include an accelerometer, a gyroscope, a compass, an image capture device (e.g., monoscopic or stereoscopic camera), a trackball, a trackpad, a touchpad, a keyboard, a cursor control device such as a mouse, a stylus, a touchscreen, proximity sensor, microphone, a bar code reader, a Quick Response (QR) code reader, electrocardiogram (ECG) sensor, PPG (photoplethysmogram) sensor, galvanic skin response sensor, any other sensor, or a radio frequency identification (RFID) reader.

The electrical device 1700 may have any desired form factor, such as a hand-held or mobile electrical device (e.g., a cell phone, a smart phone, a mobile internet device, a music player, a tablet computer, a laptop computer, a 2-in-1 convertible computer, a portable all-in-one computer, a netbook computer, an ultrabook computer, a personal digital assistant (PDA), an ultra mobile personal computer, a portable gaming console, etc.), a desktop electrical device, a server, a rack-level computing solution (e.g., blade, tray or sled computing systems), a workstation or other networked computing component, a printer, a scanner, a monitor, a set-top box, an entertainment control unit, a stationary gaming console, smart television, a vehicle control unit, a digital camera, a digital video recorder, a wearable electrical device or an embedded computing system (e.g., computing systems that are part of a vehicle, smart home appliance, consumer electronics product or equipment, manufacturing equipment). In some embodiments, the electrical device 1700 may be any other electronic device that processes data. In some embodiments, the electrical device 1700 may comprise multiple discrete physical components. Given the range of devices that the electrical device 1700 can be manifested as in various embodiments, in some embodiments, the electrical device 1700 can be referred to as a computing device or a computing system.

While the concepts of the present disclosure are susceptible to various modifications and alternative forms, specific embodiments thereof have been shown by way of example in the drawings and are described herein in detail. It should be understood, however, that there is no intent to limit the concepts of the present disclosure to the particular forms disclosed, but on the contrary, the intention is to cover all modifications, equivalents, and alternatives consistent with the present disclosure and the appended claims.

In the drawings, some structural or method features may be shown in specific arrangements and/or orderings. However, it should be appreciated that such specific arrangements and/or orderings may not be required. Rather, in some embodiments, such features may be arranged in a different manner and/or order than shown in the illustrative figures. Additionally, the inclusion of a structural or method feature in a particular figure is not meant to imply that such feature is required in all embodiments and, in some embodiments, may not be included or may be combined with other features. Further, it should be understood that the various embodiments shown in the figures are illustrative representations and are not necessarily drawn to scale.

Moreover, the illustrations and/or descriptions of various embodiments may be simplified or approximated for ease of understanding, and as a result, they may not necessarily reflect the level of precision nor variation that may be present in actual embodiments. For example, while some figures generally indicate straight lines, right angles, and smooth surfaces, actual implementations of the disclosed embodiments may have less than perfect straight lines and right angles, and some features may have surface topography or otherwise be non-smooth, given real-world limitations of fabrication processes. Similarly, illustrations and/or descriptions of how components are arranged may be simplified or approximated for ease of understanding and may vary by some margin of error in actual embodiments (e.g., due to fabrication processes, etc.).

The terms “over”, “to”, “between” and “on” as used herein may refer to a relative position of one layer with respect to other layers. One layer “over” or “on” another layer or bonded “to” another layer may be directly in contact with the other layer or may have one or more intervening layers. One layer “between” layers may be directly in contact with the layers or may have one or more intervening layers.

The term “package” generally refers to a self-contained carrier of one or more dice, where the dice are attached to the package substrate, and may be encapsulated for protection, with integrated or wire-bonded interconnects between the dice and leads, pins or bumps located on the external portions of the package substrate. The package may contain a single die, or multiple dice, providing a specific function. The package is usually mounted on a printed circuit board for interconnection with other packaged integrated circuits and discrete components, forming a larger circuit.

The term “cored” generally refers to a substrate of an integrated circuit package built upon a board, card or wafer comprising a non-flexible stiff material. Typically, a small printed circuit board is used as a core, upon which integrated circuit device and discrete passive components may be soldered. Typically, the core has vias extending from one side to the other, allowing circuitry on one side of the core to be coupled directly to circuitry on the opposite side of the core. The core may also serve as a platform for building up layers of conductors and dielectric materials.

The term “coreless” generally refers to a substrate of an integrated circuit package having no core. The lack of a core allows for higher-density package architectures, as the through-vias have relatively large dimensions and pitch compared to high-density interconnects.

The term “land side”, if used herein, generally refers to the side of the substrate of the integrated circuit package closest to the plane of attachment to a printed circuit board, motherboard, or other package. This is in contrast to the term “die side”, which is the side of the substrate of the integrated circuit package to which the die or dice are attached.

The term “dielectric” generally refers to any number of non-electrically conductive materials that make up the structure of a package substrate. For purposes of this disclosure, dielectric material may be incorporated into an integrated circuit package as layers of laminate film or as a resin molded over integrated circuit dice mounted on the substrate.

The term “metallization” generally refers to metal layers formed over and through the dielectric material of the package substrate. The metal layers are generally patterned to form metal structures such as traces and bond pads. The metallization of a package substrate may be confined to a single layer or in multiple layers separated by layers of dielectric.

The term “bond pad” generally refers to metallization structures that terminate integrated traces and vias in integrated circuit packages and dies. The term “solder pad” may be occasionally substituted for “bond pad” and carries the same meaning.

The term “solder bump” generally refers to a solder layer formed on a bond pad. The solder layer typically has a round shape, hence the term “solder bump”.

The term “substrate” generally refers to a planar platform comprising dielectric and metallization structures. The substrate mechanically supports and electrically couples one or more IC dies on a single platform, with encapsulation of the one or more IC dies by a moldable dielectric material. The substrate generally comprises solder bumps as bonding interconnects on both sides. One side of the substrate, generally referred to as the “die side”, comprises solder bumps for chip or die bonding. The opposite side of the substrate, generally referred to as the “land side”, comprises solder bumps for bonding the package to a printed circuit board.

The term “assembly” generally refers to a grouping of parts into a single functional unit. The parts may be separate and are mechanically assembled into a functional unit, where the parts may be removable. In another instance, the parts may be permanently bonded together. In some instances, the parts are integrated together.

The terms “coupled” or “connected” means a direct or indirect connection, such as a direct electrical, mechanical, magnetic or fluidic connection between the things that are connected or an indirect connection, through one or more passive or active intermediary devices.

The term “circuit” or “module” may refer to one or more passive and/or active components that are arranged to cooperate with one another to provide a desired function. The term “signal” may refer to at least one current signal, voltage signal, magnetic signal, or data/clock signal. The meaning of “a,” “an,” and “the” include plural references. The meaning of “in” includes “in” and “on.”

The vertical orientation is in the z-direction and it is understood that recitations of “top”, “bottom”, “above” and “below” refer to relative positions in the z-dimension with the usual meaning. However, it is understood that embodiments are not necessarily limited to the orientations or configurations illustrated in the figure.

The terms “substantially,” “close,” “approximately,” “near,” and “about,” generally refer to being within +/−10% of a target value (unless specifically specified). Unless otherwise specified the use of the ordinal adjectives “first,” “second,” and “third,” etc., to describe a common object, merely indicate that different instances of like objects to which are being referred and are not intended to imply that the objects so described must be in a given sequence, either temporally, spatially, in ranking or in any other manner.

For the purposes of the present disclosure, phrases “A and/or B” and “A or B” mean (A), (B), or (A and B). For the purposes of the present disclosure, the phrase “A, B, and/or C” means (A), (B), (C), (A and B), (A and C), (B and C), or (A, B and C).

Views labeled “cross-sectional”, “profile” and “plan” correspond to orthogonal planes within a cartesian coordinate system. Thus, cross-sectional and profile views are taken in the x-z plane, and plan views are taken in the x-y plane. Typically, profile views in the x-z plane are cross-sectional views. Where appropriate, drawings are labeled with axes to indicate the orientation of the figure.

### EXAMPLE EMBODIMENTS

Illustrative examples of the technologies described throughout this disclosure are provided below. Embodiments of these technologies may include any one or more, and any combination of, the examples described below. In some embodiments, at least one of the systems or components set forth in one or more of the preceding figures may be configured to perform one or more operations, techniques, processes, and/or methods as set forth in the following examples.

Example 1 includes a direct injection device, comprising: a reservoir to store liquid; a head to control extrusion of the liquid; a plunger to compress the liquid in the reservoir, wherein the plunger is controlled by the head; and a plurality of needles, wherein when the head causes the plunger to compress the liquid in the reservoir, the liquid is extruded through the plurality of needles.

Example 2 includes the direct injection device of Example 1, further comprising a needle array module, wherein the needle array module comprises the plurality of needles, and wherein the needle array module is interchangeable with one or more other needle array modules, wherein each needle array module has a different needle array configuration.

Example 3 includes the direct injection device of Example 2, wherein each needle array configuration comprises: a number of needles; an arrangement of needles; a needle length; or a needle diameter.

Example 4 includes the direct injection device of any of Examples 1-3, wherein at least one of the plurality of needles comprises a tapered tip.

Example 5 includes the direct injection device of any of Examples 1-4, wherein the head comprises: a screw-driven head; or a pneumatic head.

Example 6 includes the direct injection device of any of Examples 1-5, wherein the liquid comprises a liquid metal.

Example 7 includes the direct injection device of Example 6, wherein the liquid metal comprises gallium, indium, tin, bromine, carbon, or oxygen.

Example 8 includes the direct injection device of any of Examples 6-7, wherein the reservoir or the plurality of needles comprises an anti-corrosive material to prevent corrosion from the liquid metal.

Example 9 includes a direct injection system, comprising: a reservoir to store liquid; and a plurality of direct injection devices, wherein individual direct injection devices comprise: a head to control extrusion of the liquid; a plunger to compress the liquid in the reservoir, wherein the plunger is controlled by the head; and a plurality of needles, wherein when the head causes the plunger to compress the liquid in the reservoir, the liquid is extruded through the plurality of needles.

Example 10 includes the direct injection system of Example 9, wherein the reservoir is shared by the plurality of direct injection devices.

Example 11 includes the direct injection system of Example 9, wherein the reservoir comprises a plurality of reservoirs, wherein individual direct injection devices comprise one of the plurality of reservoirs.

Example 12 includes the direct injection system of Example 11, wherein the plurality of direct injection devices each move independently.

Example 13 includes the direct injection system of any of Examples 9-12, wherein individual direct injection devices further comprise a needle array module, wherein the needle array module comprises the plurality of needles, and wherein the needle array module is interchangeable with one or more other needle array modules, wherein each needle array module has a different needle array configuration.

Example 14 includes the direct injection system of Example 13, wherein each needle array configuration comprises: a number of needles; an arrangement of needles; a needle length; or a needle diameter.

Example 15 includes the direct injection system of any of Examples 9-14, wherein at least one of the plurality of needles comprises a tapered tip.

Example 16 includes the direct injection system of any of Examples 9-15, wherein the head comprises: a screw-driven head; or a pneumatic head.

Example 17 includes the direct injection system of any of Examples 9-16, wherein the liquid comprises a liquid metal.

Example 18 includes the direct injection system of Example 17, wherein the liquid metal comprises gallium, indium, tin, bromine, carbon, or oxygen.

Example 19 includes a method of forming a liquid metal interconnect in a substrate, comprising: moving a direct injection device to a plurality of positions above the substrate, wherein the direct injection device comprises a plurality of needles; and filling, at each position, a set of holes in the substrate with liquid metal using the direct injection device, wherein the plurality of needles simultaneously dispense liquid metal into the set of holes at each position.

Example 20 includes the method of Example 19, further comprising: attaching the liquid metal interconnect to an integrated circuit device.

1. A direct injection device, comprising:
a reservoir to store liquid;
a head to control extrusion of the liquid;
a plunger to compress the liquid in the reservoir, wherein the plunger is controlled by the head; and
a plurality of needles, wherein when the head causes the plunger to compress the liquid in the reservoir, the liquid is extruded through the plurality of needles.

2. The direct injection device of claim 1, further comprising a needle array module, wherein the needle array module comprises the plurality of needles, and wherein the needle array module is interchangeable with one or more other needle array modules, wherein each needle array module has a different needle array configuration.

3. The direct injection device of claim 2, wherein each needle array configuration comprises:
a number of needles;
an arrangement of needles;
a needle length; or
a needle diameter.

4. The direct injection device of claim 1, wherein at least one of the plurality of needles comprises a tapered tip.

5. The direct injection device of claim 1, wherein the head comprises:
a screw-driven head; or
a pneumatic head.

6. The direct injection device of claim 1, wherein the liquid comprises a liquid metal.

7. The direct injection device of claim 6, wherein the liquid metal comprises gallium, indium, tin, bromine, carbon, or oxygen.

8. The direct injection device of claim 6, wherein the reservoir or the plurality of needles comprises an anti-corrosive material to prevent corrosion from the liquid metal.

9. A direct injection system, comprising:
a reservoir to store liquid; and
a plurality of direct injection devices, wherein individual direct injection devices comprise:
a head to control extrusion of the liquid;
a plunger to compress the liquid in the reservoir, wherein the plunger is controlled by the head; and
a plurality of needles, wherein when the head causes the plunger to compress the liquid in the reservoir, the liquid is extruded through the plurality of needles.

10. The direct injection system of claim 9, wherein the reservoir is shared by the plurality of direct injection devices.

11. The direct injection system of claim 9, wherein the reservoir comprises a plurality of reservoirs, wherein individual direct injection devices comprise one of the plurality of reservoirs.

12. The direct injection system of claim 11, wherein the plurality of direct injection devices each move independently.

13. The direct injection system of claim 9, wherein individual direct injection devices further comprise a needle array module, wherein the needle array module comprises the plurality of needles, and wherein the needle array module is interchangeable with one or more other needle array modules, wherein each needle array module has a different needle array configuration.

14. The direct injection system of claim 13, wherein each needle array configuration comprises:
a number of needles;
an arrangement of needles;
a needle length; or
a needle diameter.

15. The direct injection system of claim 9, wherein at least one of the plurality of needles comprises a tapered tip.

16. The direct injection system of claim 9, wherein the head comprises:
a screw-driven head; or
a pneumatic head.

17. The direct injection system of claim 9, wherein the liquid comprises a liquid metal.

18. The direct injection system of claim 17, wherein the liquid metal comprises gallium, indium, tin, bromine, carbon, or oxygen.

19. A method of forming a liquid metal interconnect in a substrate, comprising:
moving a direct injection device to a plurality of positions above the substrate, wherein the direct injection device comprises a plurality of needles; and
filling, at each position, a set of holes in the substrate with liquid metal using the direct injection device, wherein the plurality of needles simultaneously dispense liquid metal into the set of holes at each position.

20. The method of claim 19, further comprising:
attaching the liquid metal interconnect to an integrated circuit device.
